(19) United States
(12) Patent Application Publication
(10) Pub. No.: US 2013/0175861 A1
(43) Pub. Date: Jul. 11, 2013

(54) CONTROL OPTION COMBINING A POWER-DOWN SIGNAL WITH AN ANALOG INPUT SIGNAL

(71) Applicant: John WYNNE, Limerick City (IE)

(72) Inventor: John WYNNE, Limerick City (IE)

(73) Assignee: ANALOG DEVICES, INC., Norwood, MA (US)

(21) Appl. No.: 13/345,108

(22) Filed: Jan. 6, 2012

(51) Int. Cl. H02J 7/34; H03K 5/22

(52) U.S. Cl. 307/24; 327/77

(57) ABSTRACT

Embodiments of the present invention provide a system and method for controlling a power down functionality for a component while limiting the number of inputs to the component. Embodiments may include a single input that may serve the dual purpose of providing both an input analog signal and a power down control. According to an embodiment, the power down threshold may be set as the defined minimum operating input voltage such that any input signals below the operating range may be interpreted as a power down command. Alternate signal ranges may be defined as indicating a power down command. According to an embodiment, an input signal having an improperly high voltage may additionally be interpreted as a power down or other predefined command such that any input signals outside of the predefined operating range may be interpreted as a power down command.

### BACKGROUND

Aspects of the present invention relate generally to the field of electronic signal processing and more specifically to limiting the number of control signals input to a component.

In certain power sensitive applications, it is necessary to power down electronic components whenever possible to conserve resources or to limit the generation of heat among the components. Such components may be powered down whenever they are not required or in use. Traditionally, components are powered down with a control input that signals the power down mode. Thus components having a power down option require two inputs, the signal being input into the component and a control signal. For example, a conventional buffer amplifier will have two input signals, an input analog signal and a control signal that indicates whether the component should enter or exit the power down state and resume standard operations.

Some components that utilize a power down feature may additionally be placed on an integrated circuit behind an isolation barrier. For example, in certain battery stack monitoring systems, some monitoring components may be electrically connected with the high voltage generated by the battery stack. Then each input to the component that crosses the barrier may require its own electrical isolation barrier. Thus it is desirable to limit the number of signals that are required to cross the electronic isolation barrier.

Therefore, there is a need in the art to reduce the number of control lines necessary to achieve power down functionality.

### BRIEF DESCRIPTION OF THE DRAWINGS

The foregoing and other aspects of various embodiments of the present invention will be apparent through examination of the following detailed description thereof in conjunction with the accompanying drawing figures in which similar reference numbers are used to indicate functionally similar elements.

FIG. 1 illustrates a simplified circuit diagram for an exemplary buffer amplifier according to an embodiment of the present invention.

FIG. 2(A) illustrates an exemplary input signal according to an embodiment of the present invention.

FIG. 2(B) illustrates an exemplary output signal according to an embodiment of the present invention.

FIG. 3(A) illustrates an exemplary input signal according to an embodiment of the present invention.

FIG. 3(B) illustrates an exemplary output signal according to an embodiment of the present invention.

FIG. 4 is a simplified flow diagram illustrating operation of a method for operating an exemplary buffer amplifier according to an embodiment of the present invention.

FIG. 5 illustrates a simplified circuit diagram for an exemplary isolator according to an embodiment of the present invention.

FIG. 6 is a simplified block diagram illustrating an exemplary monitoring system according to an embodiment of the present invention.

### DETAILED DESCRIPTION

Embodiments of the present invention provide a system and method for implementing a power down functionality for a component while limiting the number of signals input to the component. A single analog signal may serve the dual purpose of both a conventional input analog signal and a power down control, thereby eliminating the need for a separate and distinct control signal. In an embodiment, the power off threshold may be set as the predefined minimum operating input voltage such that any ‘invalid’ or improperly low input signals may be interpreted as a power down command. Alternate signal ranges may additionally be defined as indicating a power down command. According to an embodiment, an input signal having an improperly high voltage may additionally be interpreted as a power down or other predefined command such that any input signals outside of the defined operating range may be interpreted as a power down command.

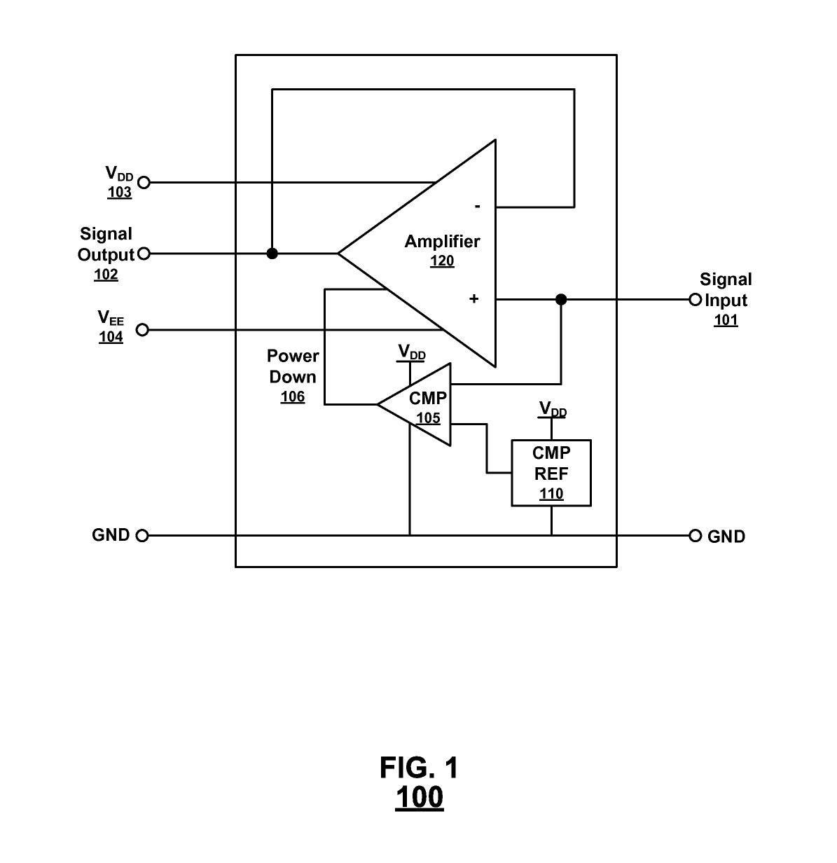

FIG. 1 illustrates a simplified circuit diagram for an exemplary buffer amplifier 100 according to an embodiment of the present invention. As shown, buffer amplifier 100 may receive a single input signal 101 and transmit an output signal 102, amplified according to the gain implemented with the amplifier 120. The buffer amplifier 100 may additionally include a controller or comparator 105, a comparator reference voltage 110, and a pair of supply voltages VDD 103 and VEE 104.

As shown in FIG. 1, the comparator 105 manages the power down operations of the buffer amplifier, however, according to an embodiment, an additional controller may be implemented as part of the buffer amplifier 100 (not shown). The controller may sample the input signal 101 to identify the input voltage, set the power down signal 106, or determine the power down threshold value.

As previously noted, the buffer amplifier 100 may have a predefined operating range, for example, +1.25V to +4.5V, and the amplifier 120 may power down whenever the voltage for the input signal 101 is below a predefined power down threshold. According to an embodiment, the power down threshold may be set equivalent to the minimum of the defined operating range (e.g., +1.25V).

To determine whether the voltage of the input 101 is below the minimum, and therefore whether the amplifier 120 is to be powered down, the comparator 105 may compare the voltage of the input 101 with the predetermined power down threshold. For example, if the power down threshold is set equivalent to the comparator reference voltage 110, and if the comparator 105 identifies an input voltage less than the comparator reference voltage 110, then the power down signal 106 may be set and the amplifier 120 may enter a power down state. If the voltage of the input 101 then rises above the comparator reference voltage 110, the power down signal 106 may be reset, the amplifier 120 may emerge from the power down state, and the input 101 may be amplified. While the input 101 is above the comparator reference voltage 110, then the power down signal 106 may not be set and the amplifier 120 may continue to operate uninterrupted.

According to an embodiment, the power down threshold may be different than the comparator reference voltage 110. Then, the power down threshold may be determined in relation to a supply voltage VDD or derived from the comparator reference voltage 110. Then the amplifier 120 may be powered down when the voltage of the input 101 is below that set threshold. For example, if the comparator reference voltage 110 is +1.25V and the input 101 has a voltage less than 1.25V below the positive supply voltage VDD, then the component might be set to a power down state. Similarly, according to an embodiment, an input 101 with a voltage above an upper threshold or above the maximum operating range may additionally trigger the power down state, or may signal an alternate instruction.

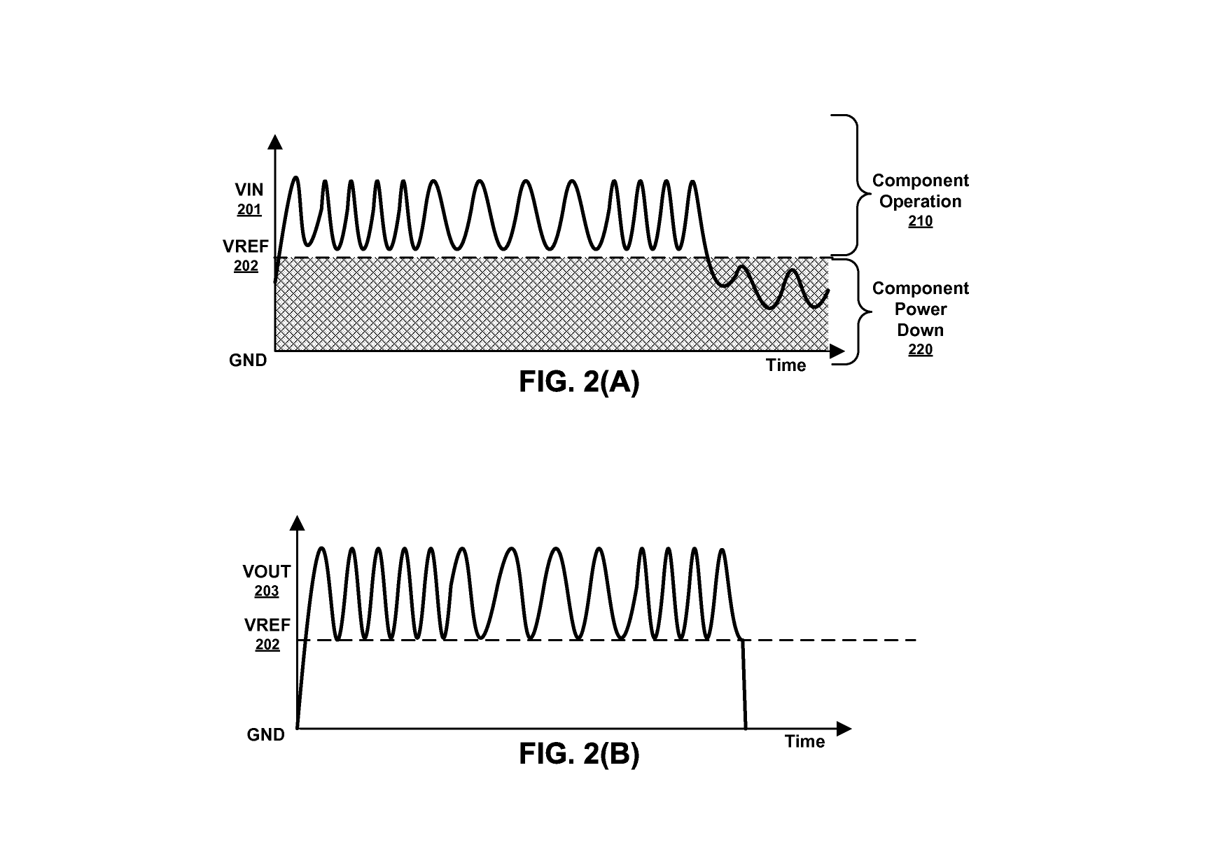

FIG. 2(A) illustrates an exemplary input signal of the exemplary buffer amplifier shown in FIG. 1. FIG. 2(B) illustrates an exemplary corresponding output signal according to an embodiment of the present invention. As shown in FIG. 2(A), the input signal 201 may vary over time, rising above or falling below the reference voltage 202. As shown in FIG. 2(B) the amplifier may power down and the corresponding output signal 203 may ideally go to zero when the input signal falls below the reference voltage 202.

As shown in FIG. 2(A) the range for the input signal 201 may be divided into at least two regions, a component operation region 210 and a component power down region 220. The two regions do not overlap but they may be adjacent so that the entire range for the input signal is considered. Any input signal 201 within the range of the component operation region 210 may be processed according to the traditional operation of the component. If the component is in a power down state, and if the input signal 201 is within the component operation region 210, the component may then emerge from the power down state and process the input signal 201. However, any input signal 201 within the component power down region 220 may cause the component to enter or remain in a power down state until a signal in the component operation region 210 is received.

When the component or amplifier powers down, the output signal may not immediately go to GND potential, but rather may gradually drift to GND potential if there is a conductive load between the amplifier output and GND (a transformer for example). When the amplifier does not have a high load, the output signal may drift near the last output signal until a new output is determined.

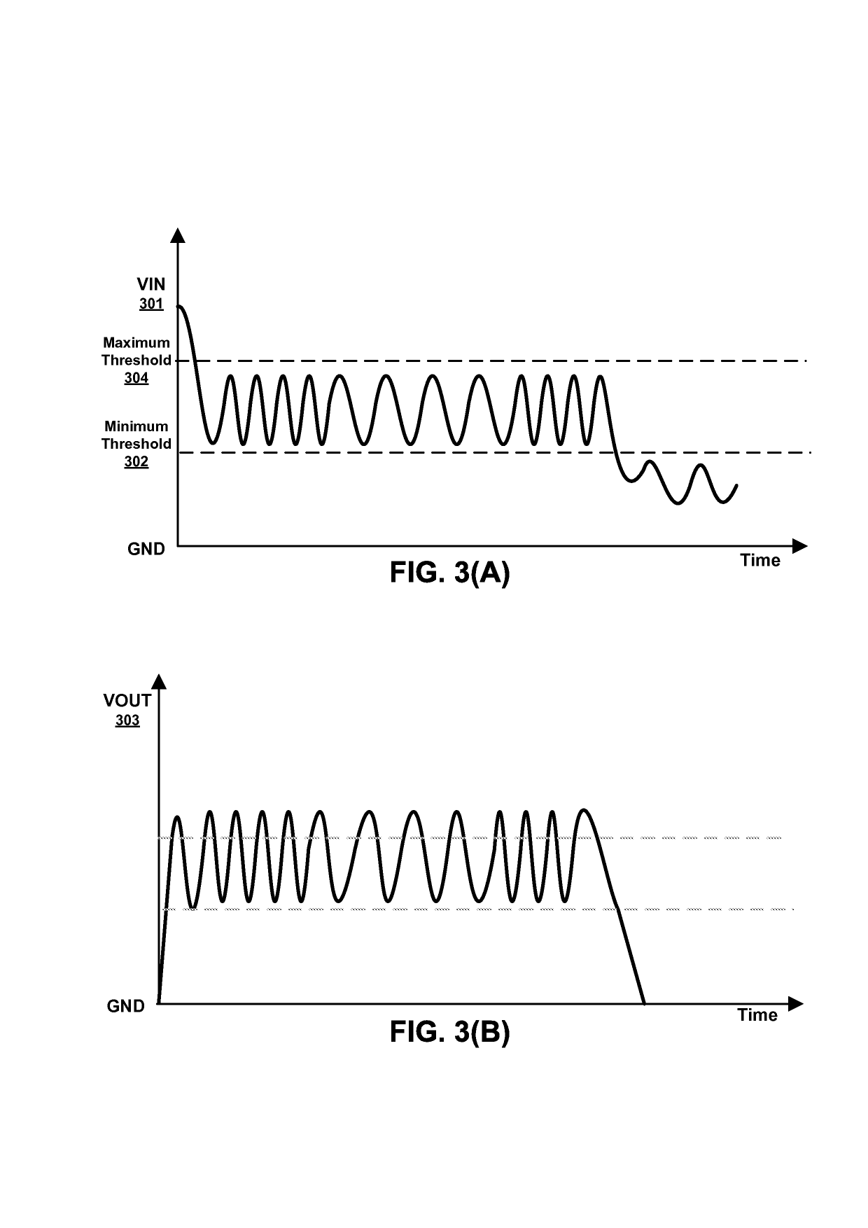

FIG. 3(A) illustrates an exemplary input signal and FIG. 3(B) an exemplary corresponding output signal according to an embodiment of the present invention. Similar to FIGS. 2(A)-2(B), the input signal 301 may vary over time, rising above and falling below the minimum power down threshold 302. As shown in FIG. 3(B) the component may power down and the corresponding output signal 303 may drift to zero when the input signal falls below the minimum power down threshold 302 and the buffer amplifier has a highly conductive load. Additionally, as previously noted, in some embodiments, when the input signal 301 rises above a second threshold 304, the maximum operating voltage for example, the improper input may additionally signal a power down condition. Then as shown in FIG. 3(B), when the input signal 301 rises above the maximum threshold 304, the amplifier may power down and the output signal 303 drift to zero.

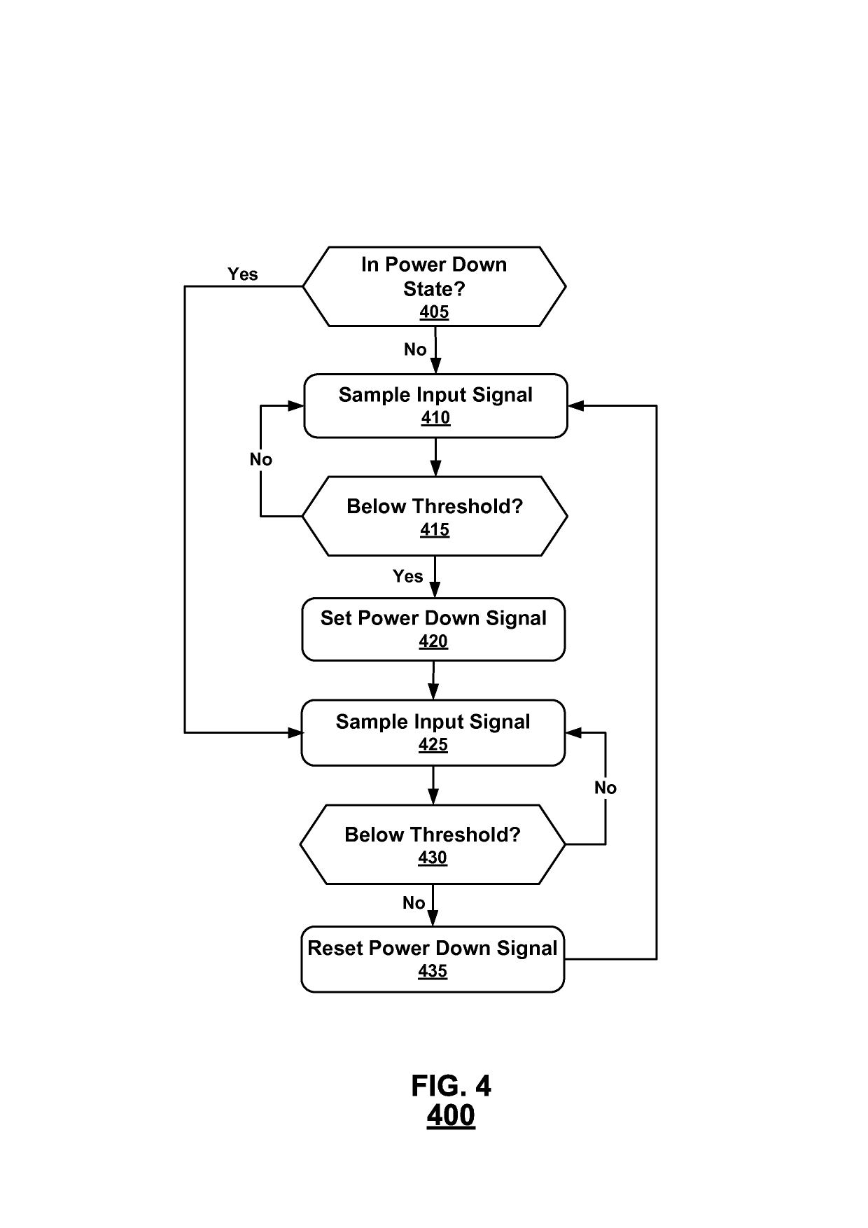

FIG. 4 is a simplified flow diagram illustrating operation of a method 400 of operating an exemplary component according to an embodiment of the present invention. As shown in FIG. 4, if the component is already in a power down state (block 405), the component may sample the voltage of the input signal until a sampled voltage above a predetermined power down threshold is determined (blocks 425-430). However, if the component is not already in a power down state (block 405), the voltage of an input signal may be sampled (block 410). Then if the sampled voltage is not below a predetermined threshold (block 415), no action need be taken and the voltage of the input signal may again be sampled (block 410). If the sampled voltage is below the predetermined threshold, then a power down signal may be set (block 420) that may cause the component to enter a power down state. The component may continue in the powered down state until a voltage above the predetermined threshold is detected for the voltage of the input signal.

Once the component is in a power down state, the voltage of the input signal may be sampled (block 425). The voltage of the input signal may be sampled until the detected voltage is above the threshold (blocks 425-430). If the sampled voltage is below the predetermined threshold (block 430), then no action need be taken and the voltage of the input signal may again be sampled. If the sampled voltage is not below the predetermined threshold, then the power down signal may be reset (block 435) which may cause the component to exit the power down state and resume operation.

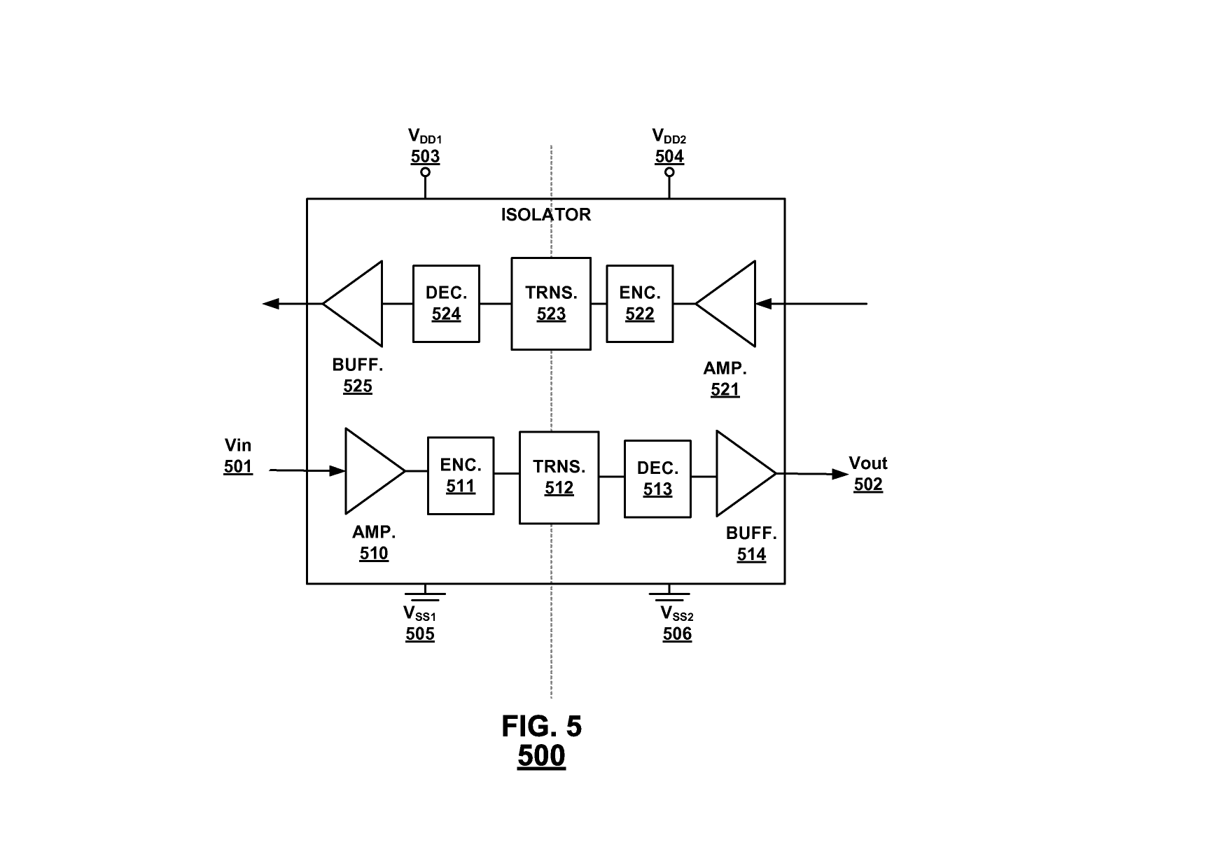

FIG. 5 illustrates a simplified circuit diagram for an exemplary isolator 500 according to an embodiment of the present invention. As shown in FIG. 5, the isolator 500 provides an electrical isolation barrier and may include a pair of communication pathways, each having a buffer amplifier 510, 521, an encoder 511, 522, a transformer 512, 523, a decoder 513, 524, and a second buffer 514, 525. Messages may be transmitted in both directions across the isolation barrier using the two communication pathways of the isolator. An input signal Vin 501 may be received and passed to the buffer amplifier 510, encoded 511 and transferred via the transformer 512 to be decoded 513, buffered 514, and output as Vout 502. Messages may similarly be passed to the buffer amplifier 521, encoded 522 and transferred via the transformer 523 to be decoded 524, buffered 525, and output.

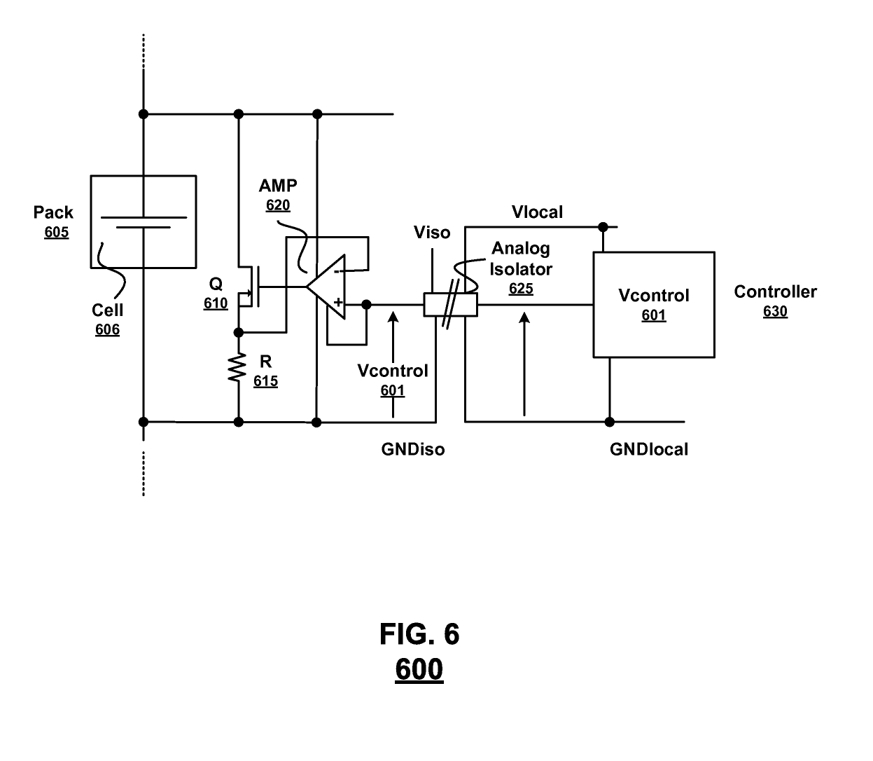

FIG. 6 is a simplified block diagram of an exemplary system 600 according to an embodiment of the present invention. As shown in FIG. 6, a passive balancing system 600 may include a voltage pack 605, a buffer amplifier 620 to control a bias circuit, an analog isolator 625, and a controller 630. A pack 605 may include one or more voltage cells 606. Each cell 606 may have a small potential difference of a few volts developed across it. Then, multiple cells arranged in series may create a larger potential difference developed across each pack such that the total potential difference developed across the pack 605 is higher than the difference developed across each cell 606. Multiple packs may be arranged in series to form a stack. Then the total potential difference of the stack may be significantly higher than for any one cell 606 or pack 605.

For example, if a pack 605 is composed of 12 cells 606, each cell 606 nominally developing 4V, then the pack 605 may develop a potential difference of 48V across the pack. However, although the cells are similar, they are not identical, so the cells may develop unequal voltages across individual packs within the stack. Ideally each pack voltage is the same. In the passive balancing scheme of FIG. 6, charge can be drained from pack 605 to reduce its pack voltage if this pack voltage is higher than other pack voltages. The voltage across each individual pack may be monitored such that some packs may be discharged if the terminal voltage gets too high.

The controller 630 may be implemented to monitor or to receive an indication of the voltage developed across each pack, determine whether the packs are balanced, and discharge the battery cells of the packs that are out of balance (terminal voltage higher than others). For each pack 605, the balancing system 600 may additionally include a bias circuit implemented in parallel with the pack 605, the bias circuit comprising a variable conductance switch 610 and resistor 615 implemented in series to drain the cells within the pack. The switch 610, and consequently the magnitude of the discharge current, may be controlled by a buffer amplifier 620 which in turn is controlled by the controller 630. The buffer amplifier may be implemented in accordance with FIG. 1 above.

The controller 630 may pass a control voltage Vcontrol 601 to the buffer amplifier 620 via the analog isolator 625. The control voltage 601 may cause the switch 610 to drain off just enough charge from the cells 606 of pack 605 to bring it down to the determined level. In accordance with the preferred embodiment variable conductance switch 610 is a linear switch ie., it can have not only on and off states but various conduction levels between on and off.

When the packs have all reached an equivalent potential, the balancing efforts may be terminated. However, to shut down the components that are no longer needed once the packs have been balanced conventionally requires two isolators, an analog isolator to bring the control voltage across the isolation barrier, as isolator 625, setting the “drain” or balance current from the module, and a digital isolator to bring an on/off signal (or power down signal) across the barrier (not shown), turning on or off the balancing functionality.

However, in accordance with an embodiment of the present invention, the buffer amplifier 620 may be controlled with a single analog input. Then the amplifier buffer 620 may be turned off when the control voltage 601 falls below the predetermined threshold.

Various embodiments may be implemented using hardware elements, software elements, or a combination of both. Determining whether an embodiment is implemented using hardware elements and/or software elements may vary in accordance with any number of factors, such as desired computational rate, power levels, heat tolerances, processing cycle budgets, input data rates, output data rates, memory resources, data bus speeds and other design or performance constraints.

Although the present application is described primarily with reference to a buffer amplifier, it would be understood by an ordinarily skilled artisan that this application may have applicability to other components that receive an input signal and have a power down option.

The foregoing discussion identifies functional blocks that may be used in signal processing systems constructed according to various embodiments of the present invention. In some applications, the functional blocks described hereinabove may be provided as elements of an integrated software system, in which the blocks may be provided as separate elements of a computer program. In other applications, the functional blocks may be provided as discrete circuit components of a processing system, such as functional units within a digital signal processor or application-specific integrated circuit. Still other applications of the present invention may be embodied as a hybrid system of dedicated hardware and software components.

Moreover, the functional blocks described herein need not be provided as separate units. Such implementation details are immaterial to the operation of the present invention unless otherwise noted above. Further, it is noted that the arrangement of the blocks in FIG. 4 does not necessarily imply a particular order or sequence of events, nor is it intended to exclude other possibilities. For example, the operations represented by blocks 410 and 425 may be executed continuously and substantially simultaneously with the operation of one or more of the remaining blocks.

While the invention has been described in detail above with reference to some embodiments, variations within the scope and spirit of the invention will be apparent to those of ordinary skill in the art. Thus, the invention should be considered as limited only by the scope of the appended claims.

What is claimed is:

1. A system comprising:
an amplifier configured to receive an input signal and to enter and exit a power down state according to a command signal; and
a comparator configured to compare a voltage of the received signal to a predetermined threshold and to set the command signal for the amplifier to enter the power down state if the received voltage is below the predetermined threshold.

2. The system of claim 1, wherein the predetermined threshold is a minimum of an operating range for the amplifier.

3. The system of claim 1, further comprising a reference voltage.

4. The system of claim 3, wherein the predetermined threshold is the reference voltage.

5. The system of claim 3, further comprising a pair of supply voltages.

6. The system of claim 5, wherein the predetermined threshold is a value less than the reference voltage.

7. An integrated circuit comprising:
an amplifier configured to receive an input analog signal; and
a comparator configured to compare a voltage of the received input analog signal to a threshold and to signal the amplifier to enter a power down state if the received voltage is below the threshold.

8. The integrated circuit of claim 7, further comprising a reference voltage.

9. The integrated circuit of claim 8, wherein the threshold is the reference voltage.

10. The integrated circuit of claim 7, further comprising a controller configured to set the threshold and to calculate the voltage of the input analog signal.

11. A method comprising:
sampling a voltage of an analog signal input to a component;
comparing with a comparator the sampled voltage to a power down threshold;
if the sampled voltage is below the power down threshold, setting a control signal to put the component in a power down state; and
if the sampled voltage is greater than or equal to the power down threshold, setting the control signal to put the component in an operational state.

12. The method of claim 11, wherein the power down threshold is a minimum of an operating range for the amplifier.

13. The method of claim 11, wherein the comparator performs said sampling.

14. The method of claim 11, wherein a controller performs said sampling.

15. The method of claim 11, further comprising setting the power down threshold.

16. The method of claim 15, wherein a controller performs said setting.

17. The method of claim 11, further comprising determining a second threshold, wherein said second threshold is greater than the power down threshold and the control signal is set to put the component in the power down state if the sampled voltage is above said second threshold.

18. The method of claim 11, wherein the component is an amplifier.

19. A system comprising:
a plurality of battery packs, each pack developing a potential voltage;
a plurality of bias circuits, each bias circuit coupled to a respective battery pack and configured to drain a portion of the voltage developed across the respective battery pack;
a plurality of buffer amplifiers, each buffer amplifier coupled to one of the plurality of bias circuits and configured to control the portion of the voltage drained from the battery pack, wherein the buffer amplifier enters a power down state upon receipt of an analog input below a predetermined threshold;
a plurality of analog isolators configured to isolate a processor from the plurality of battery packs; and
a processor to determine the amount of drain for each pack needed to balance the battery packs and to transmit an analog signal to a buffer amplifier via a respective analog isolator.

20. The system of claim 19, further comprising:
an amplifier configured to receive an input analog signal; and
a comparator configured to compare a voltage of the received input analog signal to a threshold and to signal the amplifier to enter a power down state if the received voltage is below the threshold.

21. The system of claim 19, wherein the isolator further comprises a reference voltage.

22. The system of claim 20, wherein the threshold is the reference voltage.
